(19) United States
(12) Patent Application Publication
(10) Pub. No.: US 2008/0122314 A1
(43) Pub. Date: May 29, 2008

(54) Acoustic wave device

(76) Inventors: Takashi Yamashita, Yokohama (JP); Keiji Tsuda, Yokohama (JP); Shunichi Aikawa, Yokohama (JP); Kazunori Inoue, Kawasaki (JP); Takashi Matsuda, Kawasaki (JP)

Correspondence Address: ARENT FOX LLP, 1050 CONNECTICUT AVENUE, N.W., SUITE 400, WASHINGTON, DC, 20036, US

(21) Appl. No.: 11/987,268

(22) Filed: Nov. 28, 2007

(30) Foreign Application Priority Data
Nov. 28, 2006 (JP) 2006-320487

(51) Int. Cl. H01L 41/08

(52) U.S. Cl. 310/313 R; 310/334

(57) ABSTRACT

An acoustic wave device includes an acoustic wave element provided on a substrate, a wiring that is provided on the substrate and is electrically connected to the acoustic wave element, a sealing portion that is provided on the substrate so as to cover the acoustic wave element and the wiring, and an insulating layer that is provided on a whole area between the substrate and the sealing portion and between the wiring and the sealing portion.

### BACKGROUND OF THE INVENTION

1. Field of the Invention

The present invention relates to an acoustic wave device, in particular, relates to an acoustic wave device having an insulating layer.

2. Description of the Related Art

A surface acoustic wave device has a comb electrode made of Interdigital Transducer (IDT) formed on a piezoelectric substrate, and uses an exciting acoustic wave caused by a supply of an electrical power to the comb electrode, and is widely known as one type of an acoustic wave device using an acoustic wave. This surface acoustic wave device is widely used for a circuit treating a radio signal in a frequency range of 45 MHz to 2 GHz such as a transmitting band pass filter, a receiving band pass filter, or an antenna duplexer.

There is developed a boundary acoustic wave device in which an acoustic wave propagates between two different mediums, in addition to the above-mentioned surface acoustic wave device. The boundary acoustic wave device has an advantage that an adhesion of a foreign particle to the surface of the two mediums does not influence on frequency change or electrical loss characteristics.

Further, there is developed an acoustic wave device that has a piezoelectric membrane resonator (FBAR: Film Bulk Acoustic Resonator) having a pair of electrodes on both faces of a piezoelectric membrane and using a thickness vibration of the piezoelectric membrane. The acoustic wave device having a piezoelectric membrane resonator is used in a frequency range of 1 GHz to 10 GHz, because the acoustic wave device has high characteristics in a high frequency range.

Recently, an art of mobile communication is greatly improved. A signal treatment device used in the mobile communication is downsized. And there is a demand for downsizing an electronic device of an acoustic wave device. It is necessary to form a cavity on a functional region that is the most important to secure the characteristics of the acoustic wave device. The functional region is composed of a surface acoustic wave element (a comb electrode composed of IDT) and a piezoelectric membrane resonator element (a region where an upper electrode and a lower electrode holding a piezoelectric membrane are overlapped).

FIG. 1 illustrates a cross sectional view of a surface acoustic wave device in accordance with a first conventional embodiment. As shown in FIG. 1, the surface acoustic wave device has a surface acoustic wave element 12 and a wiring 14. The surface acoustic wave element 12 has a comb electrode that is formed on a surface of a piezoelectric substrate 10 and is made of a metal membrane, a reflector and so on. The surface acoustic wave device is connected to a terminal 33 that is flip-chip mounted on a ceramics package 18 with a solder ball 16. A cavity 20 is formed between a functional region of the surface acoustic wave element 12 and the ceramics package 18. A metal rid 22 is formed on the ceramics package 18. The surface acoustic wave element 12 is thus sealed.

The surface acoustic wave device in accordance with the first conventional embodiment has a structure in which the ceramics package 18 covers the piezoelectric substrate 10 having the surface acoustic wave element 12 thereon, in order to form the cavity 20 on the functional region of the surface acoustic wave element 12. However, with the structure, the ceramics package 18 occupies the majority of the surface acoustic wave device. It is therefore difficult to downsize the surface acoustic wave device. And it is difficult to reduce a cost of the surface acoustic wave device, because the ceramics package 18 is expensive.

And so, a surface acoustic wave device in accordance with a second conventional embodiment is being developed for a purpose of reducing a size and a cost. The surface acoustic wave device has a structure in which the surface acoustic wave element 12 and the wiring 14 are covered with a resin-made sealing portion 24 including the cavity 20 on the functional region of the surface acoustic wave element 12 formed on the piezoelectric substrate 10. In the surface acoustic wave device, a penetrating electrode 32 is formed on the piezoelectric substrate 10, passes through the sealing portion 24, and electrically connects the surface acoustic wave element 12 to outside. And the solder ball 16 is formed on the penetrating electrode 32.

The surface acoustic wave device in accordance with the second conventional embodiment has a wafer level package (WLP) structure in which the sealing portion 24 including the cavity 20 on the piezoelectric substrate 10 protects the surface acoustic wave element 12 and is used instead of a package. The surface acoustic wave device can be flip-chip mounted, because the penetrating electrode 32 and the solder ball 16 are formed on the piezoelectric substrate 10. It is therefore possible to downsize the surface acoustic wave device, because an electrical signal may be input and output between the surface acoustic wave element 12 and outside with the penetrating electrode 32 formed on the piezoelectric substrate 10.

Japanese Patent Application Publication No. 2006-108993 discloses a surface acoustic wave device in which the sealing portion 24 including the cavity 20 on the functional region on the surface acoustic wave element 12 is made of a laminated membrane.

However, the surface acoustic wave device in accordance with the second conventional embodiment has the sealing portion 24 on the piezoelectric substrate 10. In particularly, the sealing portion 24 is contact to the piezoelectric substrate 10 and the wiring 14 made of the metal membrane. The sealing portion 24 is made of a resin. This results in a problem that adhesiveness is low between the resin and the piezoelectric substrate 10 and between the resin and the wiring 14. This results in a problem that the laminated membrane may be peeled between the sealing portion 24 and the piezoelectric substrate 10 and between the sealing portion 24 and the wiring 14, because the sealing portion 24 is subjected to a stress in a manufacturing process of the surface acoustic wave device.

In particularly, the penetrating electrode 32 is formed on the piezoelectric substrate 10 in order to downsize the surface acoustic wave device in accordance with the second conventional embodiment. Therefore, a contact area is reduced between the sealing portion 24 and the piezoelectric substrate 10 and between the sealing portion 24 and the wiring 14, and the adhesiveness is reduced between the sealing portion 24 and the piezoelectric substrate 10 and between the sealing portion 24 and the wiring 14. This results in a problem that the laminated membrane may be peeled between the sealing portion 24 and the piezoelectric substrate 10 and between the sealing portion 24 and the wiring 14.

It is necessary to enlarge the thickness of the sealing portion 24 in order to obtain a sufficient strength of the sealing portion 24, because the strength of the resin is relatively low. However, the stress subjected to the sealing portion 24 in the manufacturing process of the surface acoustic wave device is more enlarged, as the thickness of the sealing portion 24 gets higher. This results in that the membrane tends to be peeled between the sealing portion 24 and the piezoelectric substrate 10 and between the sealing portion 24 and the wiring 14.

Further, it is necessary to form the cavity 20 on the functional region of the surface acoustic wave element 12 in the surface acoustic wave device. It is therefore necessary to enlarge the thickness of the sealing portion 24 more, in order to obtain a sufficient strength of the sealing portion 24. And, the contact area between the sealing portion 24 and the piezoelectric substrate 10 and between the sealing portion 24 and the wiring 14 is more reduced because of the cavity 20. This results in that the membrane tends to be peeled between the sealing portion 24 and the piezoelectric substrate 10 and between the sealing portion 24 and the wiring 14.

### SUMMARY OF THE INVENTION

The present invention has been made in view of the above circumstances, and provides a surface acoustic wave device having a high reliability in which adhesiveness is improved between a sealing portion and a substrate and between the sealing portion and a wiring.

According to an aspect of the present invention, there is provided an acoustic wave device including an acoustic wave element provided on a substrate, a wiring that is provided on the substrate and is electrically connected to the acoustic wave element, a sealing portion that is provided on the substrate so as to cover the acoustic wave element and the wiring, and an insulating layer that is provided on a whole area between the substrate and the sealing portion and between the wiring and the sealing portion. With the structure, it is possible to improve adhesiveness between the sealing portion and the substrate and between the sealing portion and the wiring. Therefore, the acoustic wave device has a high reliability.

### BRIEF DESCRIPTION OF THE DRAWINGS

Preferred embodiments of the present invention will be described in detail with reference to the following drawings, wherein:

FIG. 1 illustrates a cross sectional view of a surface acoustic wave device in accordance with a first conventional embodiment;

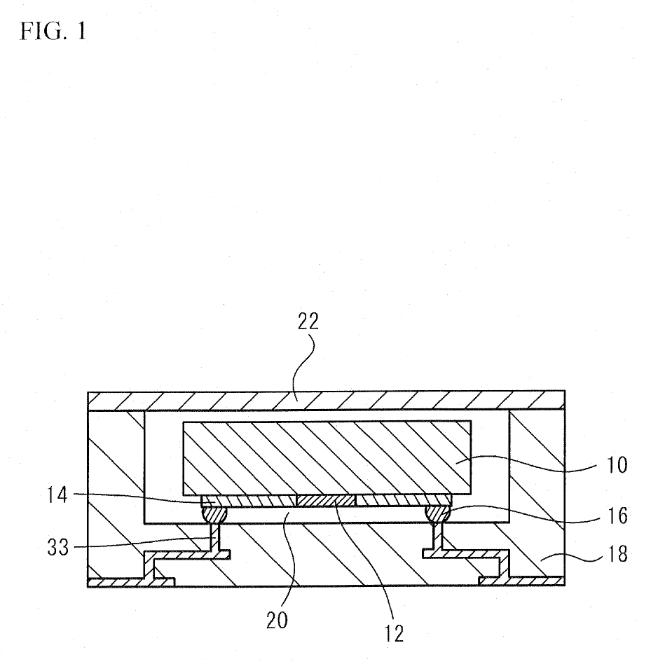

FIG. 2 illustrates a cross sectional view of a surface acoustic wave device in accordance with a first comparative embodiment;

FIG. 3A through FIG. 3D illustrate a manufacturing method of the surface acoustic wave device in accordance with the first comparative embodiment;

FIG. 4A through FIG. 4C illustrate the manufacturing method of the surface acoustic wave device in accordance with the first comparative embodiment;

FIG. 5 illustrates a schematic view of a SEM image showing a problem of the surface acoustic wave device in accordance with the first comparative embodiment;

FIG. 6 illustrates a cross sectional view of a surface acoustic wave device in accordance with a first embodiment;

FIG. 7A through FIG. 7C illustrate a manufacturing method of the surface acoustic wave device in accordance with the first embodiment;

FIG. 8A through FIG. 8C illustrate the manufacturing method of the surface acoustic wave device in accordance with the first embodiment;

FIG. 9A through FIG. 9C illustrate the manufacturing method of the surface acoustic wave device in accordance with the first embodiment; and

FIG. 10 illustrates an advantage of the surface acoustic wave device in accordance with the first embodiment.

### DESCRIPTION OF THE PREFERRED EMBODIMENTS

A description will now be given, with reference to the accompanying drawings, of embodiments of the present invention.

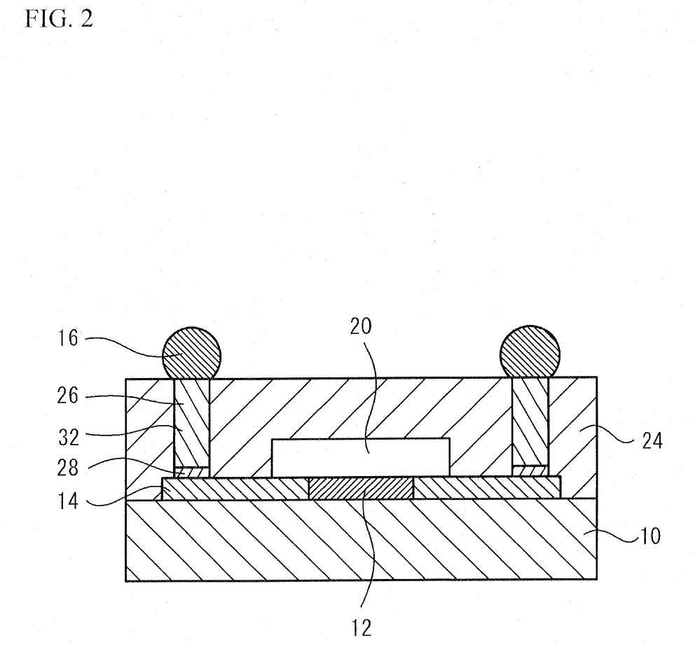

A description will be given of an example for clarifying a problem of the surface acoustic wave device in accordance with the second conventional embodiment. FIG. 2 illustrates a cross sectional view of an examined surface acoustic wave device in accordance with a first comparative embodiment. As shown in FIG. 2, the surface acoustic wave device has the surface acoustic wave element 12 and the wiring 14 that are made of Al (aluminum) on the piezoelectric substrate 10. The surface acoustic wave element 12 is composed of a comb electrode, a resonator and so on. The piezoelectric substrate 10 is made of LiTaO₃ (lithium tantalate). The wiring 14 is electrically connected to the surface acoustic wave element 12. The sealing portion 24 includes the cavity 20 formed on the functional region of the surface acoustic wave element 12. The sealing portion 24 is provided on the piezoelectric substrate 10 so as to cover the surface acoustic wave element 12 and the wiring 14, has a thickness of 60 μm, and is made of a photosensitive epoxy resin. An opening 26 is formed in the sealing portion 24 above the wiring 14. A pad electrode 28 is made of Ti (titanium) and Au (gold), and is formed on the wiring 14 in the opening 26. The penetrating electrode 32 is made of Cu, and is formed in the opening 26 on the pad electrode 28. The solder ball 16 is made of SnAg, and is formed on the penetrating electrode 32. The penetrating electrode 32 passes through the sealing portion 24, and inputs and outputs an electrical signal between the surface acoustic wave element 12 and outside from the surface of the piezoelectric substrate 10 via the wiring 14.

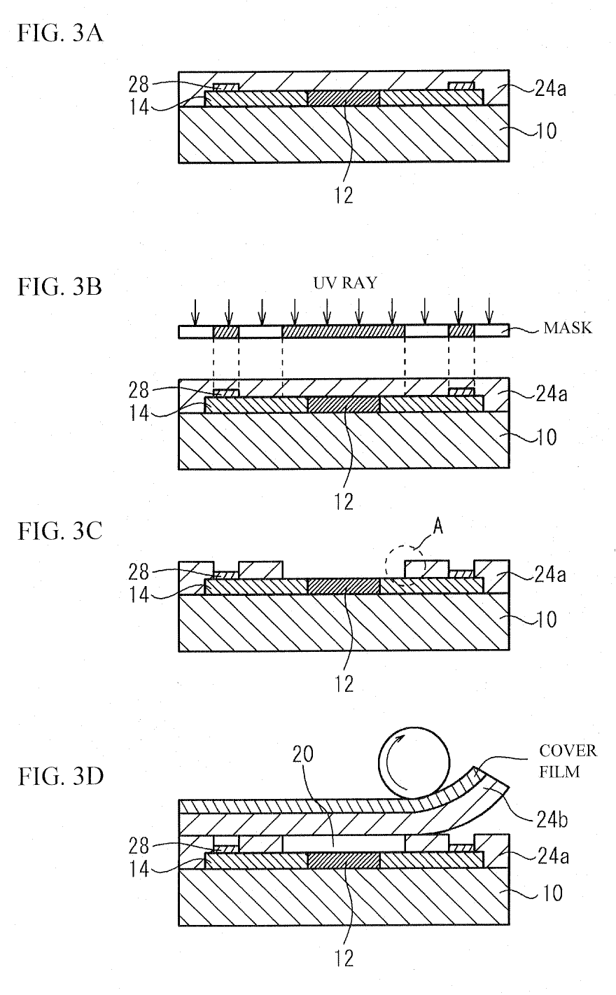

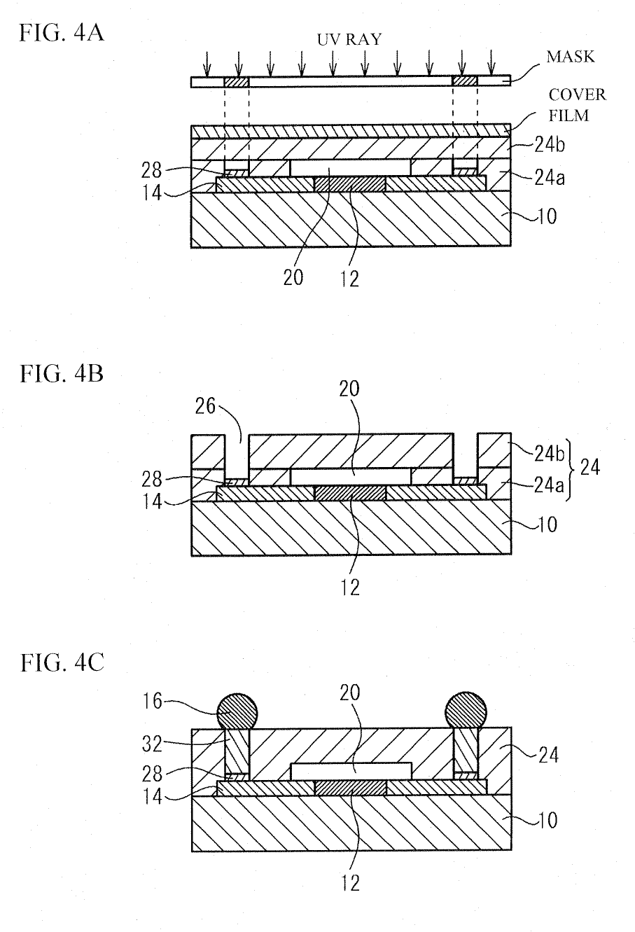

A description will be given of a manufacturing method of the surface acoustic wave device in accordance with the first comparative embodiment, with reference to FIG. 3A through FIG. 4C.

As shown in FIG. 3A, a first sealing portion 24a is spin-coated on the piezoelectric substrate 10 having the wiring 14 and the pad electrode 28 thereon. The first sealing portion 24a is made of a photosensitive epoxy resin and has a thickness of 30 μm. As shown in FIG. 3B, an ultraviolet ray (UV ray) is radiated to the first sealing portion 24a with use of a mask. And the first sealing portion 24a is exposed. As shown in FIG. 3C, a given region of the first sealing portion 24a where the ultraviolet ray is not radiated is removed when the first sealing portion 24a is developed. Thus, the first sealing portion 24a on the functional region and on the pad electrode 28 is removed. This results in that the first sealing portion 24a is formed so as to surround the functional region of the surface acoustic wave element 12. After that, the first sealing portion 24a is hardened with a baking at 250 degrees C. As shown in FIG. 3D, a second sealing portion 24b is laminated on the first sealing portion 24a. The second sealing portion 24b is made of a photosensitive epoxy resin and has a thickness of 30 μm. Therefore, the functional region of the surface acoustic wave element 12 is covered. And the cavity 20 is formed on the functional region of the surface acoustic wave element 12.

As shown in FIG. 4A, an ultraviolet ray (UV ray) is radiated to the second sealing portion 24b with use of a mask, and the second sealing portion 24b is exposed. As shown in FIG. 4B, the second sealing portion 24b is developed, and a region of the second sealing portion 24b where the ultraviolet ray is not radiated is removed. After that, the second sealing portion 24b is hardened with a baking at 250 degrees C. Thus the sealing portion 24 composed of the first sealing portion 24a and the second sealing portion 24b is formed. As shown in FIG. 4C, a Cu coating is formed in the opening 26 on the pad electrode 28 with an electroplating. The opening 26 on the pad electrode 28 is subjected to a flash plating of Au, and the penetrating electrode 32 is formed. After that, a SnAg solder ball is mounted on the penetrating electrode 32, or a SnAg solder paste is mask-printed and reflowed on the penetrating electrode 32. This results in a formation of the solder ball 16. With the processes, the surface acoustic wave device in accordance with the comparative embodiment is manufactured.

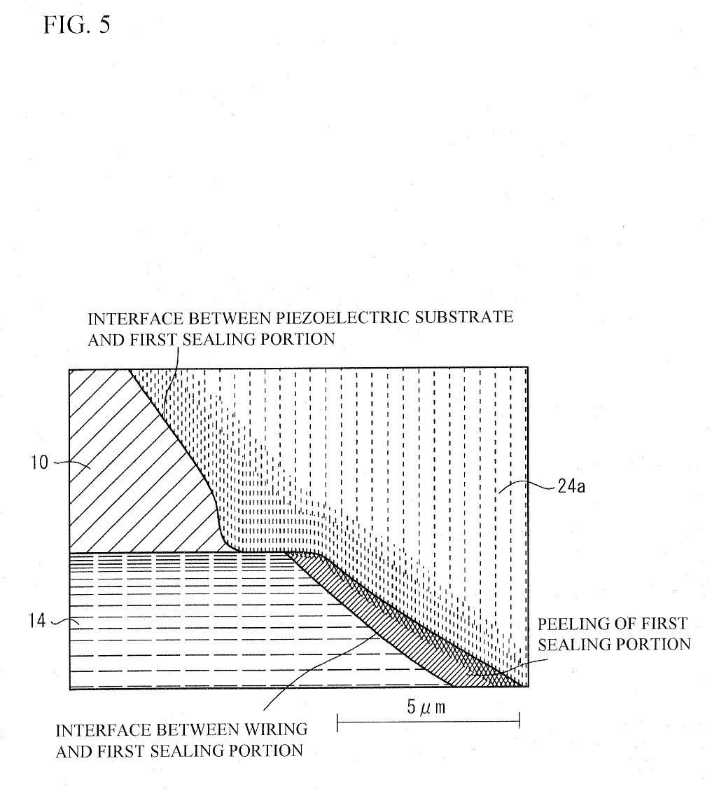

FIG. 5 illustrates a schematic view of a SEM image between the piezoelectric substrate 10 and the first sealing portion 24a and between the wiring 14 and the first sealing portion 24a, in a case where a region A shown in the manufacturing process of the surface acoustic wave device in accordance with the first comparative embodiment is viewed from an upper angle. As shown in FIG. 5, the piezoelectric substrate 10 is adhered to the first sealing portion 24a. However, the first sealing portion 24a is peeled from the wiring 14 at an interface between the first sealing portion 24a and the wiring 14.

In the manufacturing process of the surface acoustic wave device in accordance with the comparative embodiment, the baking is performed at 250 degrees C. in order to harden the first sealing portion 24a as shown in FIG. 3C. As a result, the first sealing portion 24a is subjected to a contraction stress. The first sealing portion 24a is peeled at an interface between the wiring 14 and the first sealing portion 24a because of the stress subjected to the first sealing portion 24a, because adhesiveness is low between the piezoelectric substrate 10 and the first sealing portion 24a and between the wiring 14 and the first sealing portion 24a. And so, a description will be given of embodiments solving the above-mentioned problem.

### First Embodiment

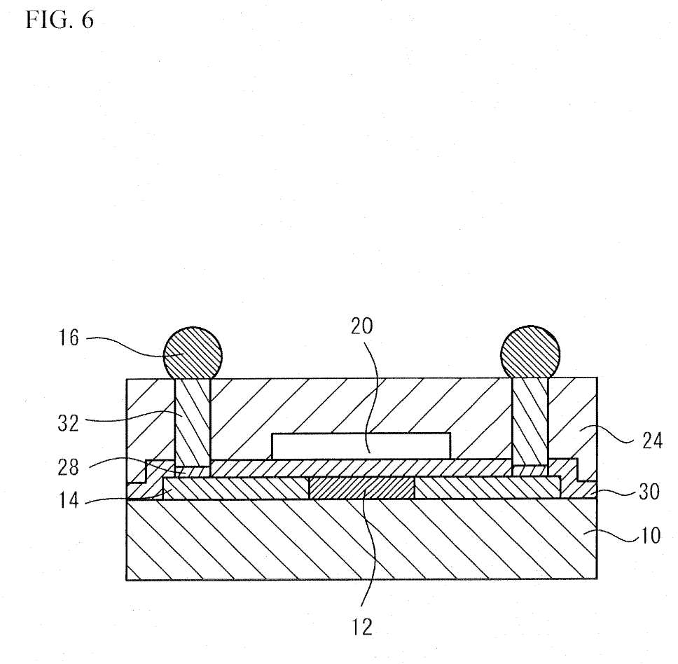

FIG. 6 illustrates a cross sectional view of a surface acoustic wave device in accordance with a first embodiment. As shown in FIG. 6, the surface acoustic wave device includes an insulating layer 30. The insulating layer 30 is made of SiO₂ (silicon oxide), has a thickness of 20 nm, and is formed between the piezoelectric substrate 10 and the sealing portion 24, between the surface acoustic wave element 12 and the sealing portion 24, and between the wiring 14 and the sealing portion 24. The other structure is the same as that of the first comparative embodiment.

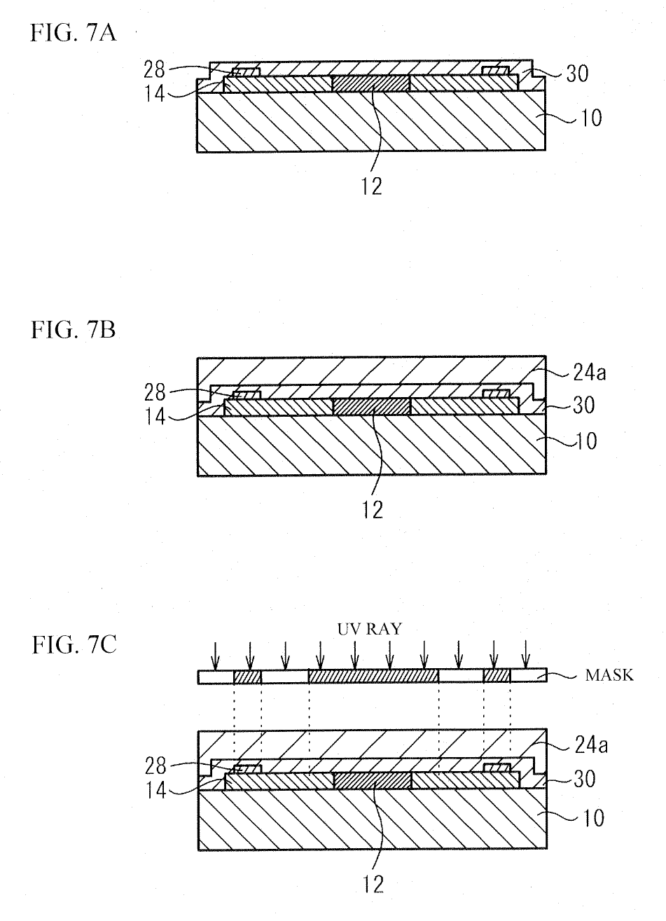

FIG. 7A through FIG. 9C illustrate a manufacturing method of the surface acoustic wave device in accordance with the first embodiment.

As shown in FIG. 7A, the insulating layer 30 is formed with a sputtering method on the piezoelectric substrate 10 that has the surface acoustic wave element 12, the wiring 14 and the pad electrode 28 thereon. The insulating layer 30 has a thickness of 20 nm and is made of SiO₂. As shown in FIG. 7B, the first sealing portion 24a is spin-coated on the insulating layer 30. The first sealing portion 24a has a thickness of 30 μm and is made of a photosensitive epoxy resin. As shown in FIG. 7C, an ultraviolet ray (UV ray) is radiated to the first sealing portion 24a with use of a mask, and the first sealing portion 24a is exposed.

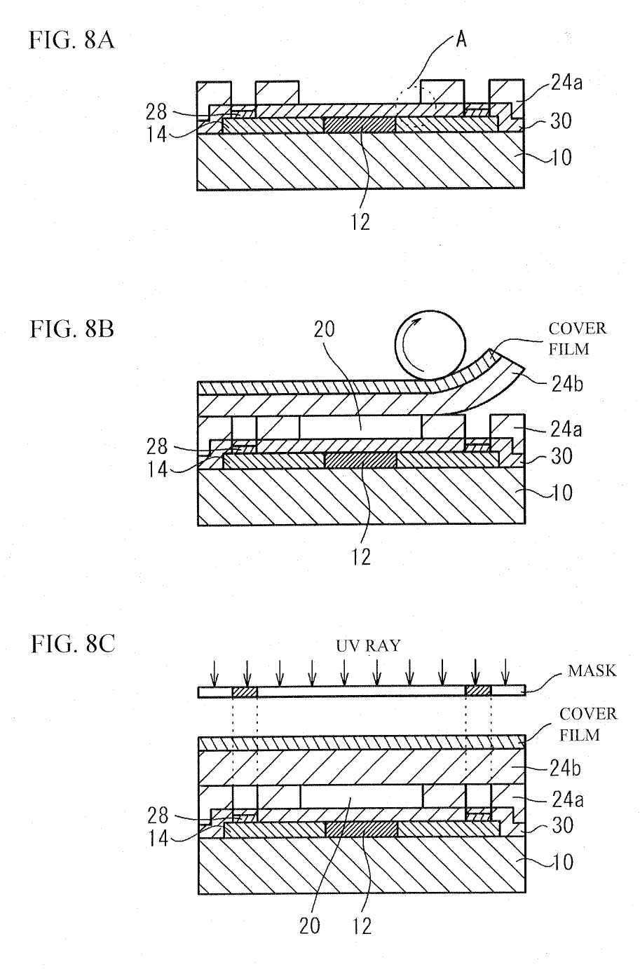

As shown in FIG. 8A, a region of the first sealing portion 24a where the ultraviolet ray (UV ray) is not radiated is removed when the first sealing portion 24a is developed. Thus, a region of the first sealing portion 24a on the functional region and on the pad electrode 28 of the surface acoustic wave element 12 is removed. Therefore, the first sealing portion 24a is formed so as to surround the functional region of the surface acoustic wave element 12. After that, the first sealing portion 24a is hardened with a baking at 250 degrees C. As shown in FIG. 8B, the second sealing portion 24b made of a photosensitive epoxy resin is laminated on the first sealing portion 24a. The functional region of the surface acoustic wave element 12 is thus covered. And the cavity 20 is formed on the functional region of the surface acoustic wave element 12. As shown in FIG. 8C, an ultraviolet ray (UV ray) is radiated to the second sealing portion 24b with use of a mask. And the second sealing portion 24b is exposed.

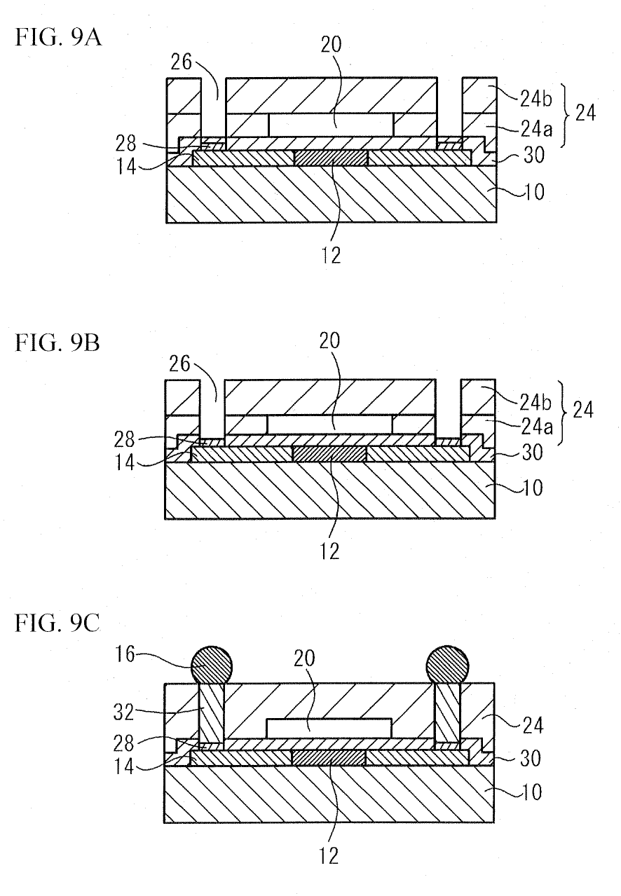

As shown in FIG. 9A, a region of the second sealing portion 24b, to which the ultraviolet ray (UV ray) is not radiated, is removed when the second sealing portion 24b is developed. After that, the second sealing portion 24b is baked at 250 degrees C. The sealing portion 24 composed of the first sealing portion 24a and the second sealing portion 24b is thus formed. As shown in FIG. 9B, a pattern is made from a photo resist. And the insulating layer 30 is subjected to an etching treatment with a RIE (Reactive Ion Etching) method. As shown in FIG. 9C, a Cu coating is formed in the opening 26 on the pad electrode 28 with an electroplating. The opening 26 is subjected to a flash plating of Au, and the penetrating electrode 32 is formed. After that, a SinAg solder ball is mounted on the penetrating electrode 32, or a SnAg solder paste is mask-printed and reflowed on the penetrating electrode 32, and the solder ball 16 is formed. With the processes, the surface acoustic wave device in accordance with the first embodiment is manufactured.

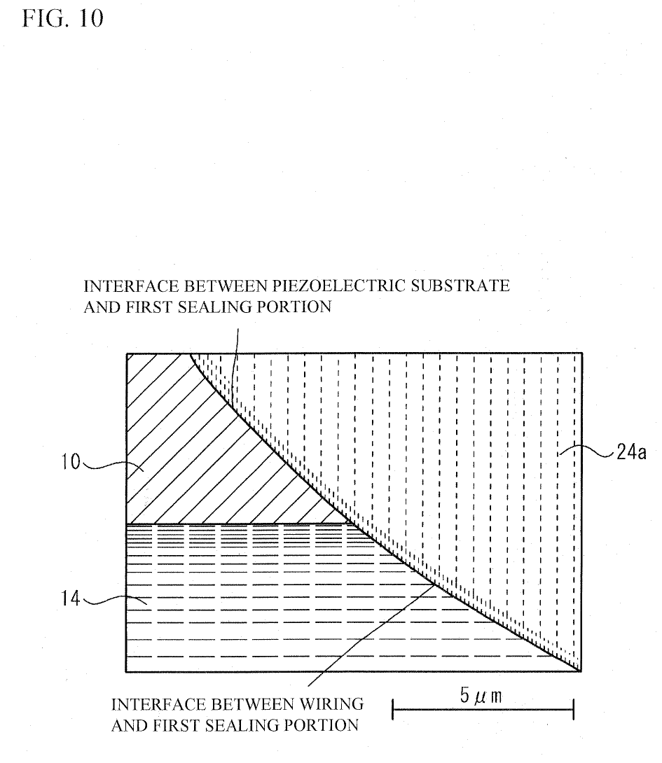

FIG. 10 illustrates a schematic view of a SEM image between the piezoelectric substrate 10 and the first sealing portion 24a and between the wiring 14 and the first sealing portion 24a, in a case where a region A shown in FIG. 8A in the manufacturing process of the surface acoustic wave device in accordance with the first embodiment is viewed from an upper angle. As shown in FIG. 10, the insulating layer 30 is formed between the piezoelectric substrate 10 and the first sealing portion 24a and between the wiring 14 and the first sealing portion 24a. Therefore, the first sealing portion 24a is not peeled at and is solidly adhered to an interface between the piezoelectric substrate 10 and the first sealing portion 24a and between the wiring 14 and the first sealing portion 24a.

In the first embodiment, the insulating layer 30 made of SiO₂ is formed on a whole area between the piezoelectric substrate 10 and the first sealing portion 24a and between the wiring 14 and the first sealing portion 24a. This results in that adhesiveness is improved between the piezoelectric substrate 10 and the first sealing portion 24a and between the wiring 14 and the first sealing portion 24a. Therefore, the first sealing portion 24a is not peeled even if the baking is performed in order to harden the first sealing portion 24a and the first sealing portion 24a is subjected to a stress in the manufacturing process of the surface acoustic wave device in accordance with the first embodiment, because the adhesiveness is improved between the piezoelectric substrate 10 and the first sealing portion 24a and between the wiring 14 and the first sealing portion 24a.

And the insulating layer 30 is also formed on the surface acoustic wave element 12 in the first embodiment. The surface acoustic wave device may be degraded when a foreign particle is on the functional region of the surface acoustic wave element 12. However, the surface acoustic wave device may be hardly degraded, because the insulating layer 30 has a thickness of 20 nm and is sufficiently thin.

In the first embodiment, the sealing portion 24 is composed of the first sealing portion 24a and the second sealing portion 24b, the first sealing portion 24a surrounding the functional region of the surface acoustic wave element 12, the second sealing portion 24b covering the functional region of the surface acoustic wave element 12 and forming the cavity 20 above the functional region of the surface acoustic wave element 12. It is therefore possible to manufacture the sealing portion 24 including the cavity 20 on the functional region of the surface acoustic wave element 12 easily.

In the first embodiment, the insulating layer 30 is formed on the whole area between the piezoelectric substrate 10 and the sealing portion 24 and between the wiring 14 and the sealing portion 24. However, the structure of the insulating layer 30 is not limited. It is possible to improve the adhesiveness between the piezoelectric substrate 10 and the sealing portion 24 and between the wiring 14 and the sealing portion 24, even if the insulating layer 30 is formed on a part of the region between the piezoelectric substrate 10 and the sealing portion 24 and between the wiring 14 and the sealing portion 24. However, it is preferable that the insulating layer 30 is formed on the whole area between the piezoelectric substrate 10 and the sealing portion 24 and between the wiring 14 and the sealing portion 24, because the adhesiveness is the highest and the sealing portion 24 most hardly tends to be peeled in the case.

In the first embodiment, the first sealing portion 24a is formed with the spin coating. However, the first sealing portion 24a may be formed with a laminating or the like.

Further, the first sealing portion 24a and the second sealing portion 24b are hardened with the baking at 250 degrees C. in the first embodiment. However, the first sealing portion 24a and the second sealing portion 24b may be baked at another temperature such as 200 degrees C. to 250 degrees C., if the first sealing portion 24a and the second sealing portion 24b can be hardened.

In the first embodiment, the insulating layer 30 has the thickness of 20 nm. However, the thickness of the insulating layer 30 is not limited. However, a coverability of the insulating layer 30 may be degraded because of a step between the surface acoustic wave element 12 and the wiring 14, if the thickness of the insulating layer 30 is too small. The characteristics of the surface acoustic wave device may be degraded because of the formation of the insulating layer 30 on the surface acoustic wave element 12, if the insulating layer 30 is too large. It is therefore preferable that the thickness of the insulating layer 30 is 10 nm to 30 nm.

Further, the sealing portion 24 is made of the photosensitive epoxy resin in the first embodiment. The sealing portion 24 may be made of another material such as a photosensitive polyimide resin. It is however preferable that the sealing portion 24 is made of a photosensitive resin, because it is possible to manufacture the surface acoustic wave device easily in the case.

Further, the insulating layer 30 is made of SiO₂. The insulating layer 30 may be made of another material. The insulating layer 30 may be made of a silicon compound such as Si₃N₄ (silicon nitride), or a composite material of SiO₂ and Si₃N₄, because it is possible to improve the adhesiveness of the sealing portion 24 in the case.

Further, the insulating layer 30 is formed between the piezoelectric substrate 10 and the sealing portion 24 of the surface acoustic wave device and between the wiring 14 and the sealing portion 24 of the surface acoustic wave device, in the first embodiment. The insulating layer 30 may be formed between a substrate of another acoustic wave device such as a boundary acoustic wave device or a piezoelectric membrane resonator (FBAR) and the sealing portion 24 and between the wiring 14 and the sealing portion 24. In this case, the advantage of the present invention can be obtained. In the case where the acoustic wave device includes the FBAR, the substrate is not a piezoelectric substrate but a silicon substrate, a glass substrate or a sapphire substrate. And the FBAR has a structure in which a piezoelectric membrane is formed on a substrate.

While the above description constitutes the preferred embodiments of the present invention, it will be appreciated that the invention is susceptible of modification, variation and change without departing from the proper scope and fair meaning of the accompanying claims.

The present application is based on Japanese Patent Application No. 2006-320487 filed Nov. 28, 2006, the entire disclosure of which is hereby incorporated by reference.

What is claimed is:

1. An acoustic wave device comprising:
an acoustic wave element provided on a substrate;
a wiring that is provided on the substrate and is electrically connected to the acoustic wave element;
a sealing portion that is provided on the substrate so as to cover the acoustic wave element and the wiring; and
an insulating layer that is provided on a whole area between the substrate and the sealing portion and between the wiring and the sealing portion.

2. The acoustic wave device as claimed in claim 1, wherein the sealing portion has a cavity on a functional region of the acoustic wave element.

3. The acoustic wave device as claimed in claim 1 further comprising a penetrating electrode that is provided on the substrate and electrically connects the acoustic wave element to outside.

4. The acoustic wave device as claimed in claim 3 further comprising a solder ball on the penetrating electrode.

5. The acoustic wave device as claimed in claim 1, wherein the sealing portion has a first sealing portion surrounding the functional region of the acoustic wave element and a second sealing portion covering the functional region and having a cavity on the functional region.

6. The acoustic wave device as claimed in claim 1, wherein the sealing portion is made of a photosensitive resin.

7. The acoustic wave device as claimed in claim 1, wherein the insulating layer is a silicon compound.

8. The acoustic wave device as claimed in claim 2, wherein the acoustic wave device is a surface acoustic wave device.
